(19) United States
(12) Patent Application Publication
(10) Pub. No.: US 2020/0312768 A1
(43) Pub. Date: Oct. 1, 2020

(54) CONTROLLED ORGANIC LAYERS TO ENHANCE ADHESION TO ORGANIC DIELECTRICS AND PROCESS FOR FORMING SUCH

(71) Applicant: Intel Corporation, Santa Clara, CA (US)

(72) Inventors: Suddhasattwa NAD, Chandler, AZ (US); Rahul MANEPALLI, Chandler, AZ (US); Srinivas PIETAMBARAM, Chandler, AZ (US); Marcel WALL, Phoenix, AZ (US)

(21) Appl. No.: 16/366,647

(22) Filed: Mar. 27, 2019

(51) Int. Cl. H01L 23/538; H01L 23/498; H01L 25/18; H01L 21/48

(52) U.S. Cl. CPC H01L 23/5384; H01L 23/49866; H01L 21/486; H01L 25/18; H01L 23/49827

(57) ABSTRACT

An interconnection structure is disclosed. The interconnection structure includes a dielectric layer, an interfacial TiC layer on the dielectric layer, the interfacial TiC layer having a uniform thickness, and a Ti layer on the TiC layer.

### TECHNICAL FIELD

Embodiments of the disclosure pertain to enhancing adhesion to organic dielectrics and, in particular, controlled organic layers for enhancing adhesion to organic dielectrics.

### BACKGROUND

Substrates for next generation chip-to-chip interconnect technologies require significantly higher speed and higher density input/output (TO) routing for enabling multi-die packing architectures. Omni-directional interconnects (ODI), high density plasma (HDP) and embedded multi-die interconnect bridge (EMIB) use a combination of decreasing fine line spacing (FLS) and multi-chip assemblies unified on a package. Embedded dies within the substrate package and/or assembled dies on the substrate package enable the creation of multi-chip electronic packages that provide system-on-a-chip (SOC) type architecture in multi-process node chiplet architectures.

These architectures require the use of high resolution solder resists (HR-SR) and photoimageable dielectrics (PID) to create panel level fan-out architectures, hyper density packaging and bump pitch scaling in EMIB/ODI architectures. Such polymers cannot be roughened by desmear chemistry due to: (a) their formulation, and (b) loss of high resolution benefit to the build-up process. Hence, electroless methods of applying the copper seed have difficulty in attaching to this material.

### BRIEF DESCRIPTION OF THE DRAWINGS

FIGS. 1A-1D illustrate cross-sections of an interconnect structure during a process for forming interconnects according to a previous approach.

FIG. 2 illustrates an interconnect structure that includes a uniform interfacial layer with enhanced adhesion according to an embodiment.

FIGS. 3A-3D illustrate cross-sections of an interconnect structure during a process for forming interconnects that have a uniform interfacial layer with enhanced adhesion according to an embodiment.

FIGS. 4A-4C illustrate example skeletal formulas of molecules that can be used to form a controlled organic layer according to an embodiment.

FIG. 5 illustrates an example of the skeletal formula of a molecule that can be used to form a controlled organic layer according to an embodiment.

FIG. 6 illustrates an example of an asymmetrical bifunctional variant that can be used to form a controlled organic layer according to an embodiment.

FIG. 7 illustrates a computer system according to an embodiment.

### DESCRIPTION OF THE EMBODIMENTS

Controlled organic layers for enhancing adhesion to organic dielectrics is described. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Ti layers exhibit lower adhesion to an organic/polymer dielectric when TiO₂ exceeds TiC at the interface of the Ti and the dielectric. Thus, the formation of TiO₂ at the interface of the Ti and the dielectric is detrimental to interfacial Ti-polymer adhesion. Previous techniques for depositing Ti result in an irregular, high thickness-variation TiC interfacial layer that includes TiO₂ components. In particular, such deposition techniques can result in a non-uniform combination TiC/TiO₂ interfacial layer.

In a previous approach physical vapor deposition (PVD/sputter) methods are used to form a thin Ti layer that improves the adhesion of the copper seed and the dielectric layer. This method is limited by the adhesion of the Ti layer to the dielectric surface. Recent experiments have shown that this Ti layer achieves lower adhesion when TiO₂ exceeds TiC (which both can be produced) at the interface of the Ti layer and the dielectric layer. Thus, the formation of TiO₂ at this interface is detrimental to interfacial Ti-polymer adhesion. Such deposition techniques can result in a non-uniform TiC/TiO₂ combination interfacial layer. As such, conventional deposition techniques can result in irregular and high thickness variation in the desirable TiC material.

An approach that addresses the shortcomings of previous approaches is disclosed herein. For example, as part of a disclosed process, a controlled organic layer such as a self-assembled monolayers (SAM) (or other controlled organic layer) is used to provide a reactive carbon rich surface on a dielectric surface. This layer acts as a controlled source of active carbon atoms to impinging Ti atoms in a physical vapor deposition (PVD) process and enables a controlled uniform formation of a TiC layer. The term uniform TiC layer as used herein is intended to refer to a TiC layer that has a non-irregular profile. In an embodiment, the uniform TiC layer improves the interfacial adhesion between the dielectric and the Ti. In an embodiment, the molecular design leverages non-interacting functional end groups to chemically bond to the surface of the dielectric material on one end (R1) while providing a reactive carbon moiety for easily forming the TiC layer at the other (R2). In an embodiment, the dielectric can be an organic dielectric. In other embodiments, the dielectric can be other types of dielectrics.

In an embodiment, the advantages of interfacial controlled organic layers include but are not limited to: (1) providing a finely controllable method of depositing a predominantly reactive carbon rich surface on the surface of high resolution solder resist (HR-SR) or photoimageable dielectric (PID) materials for improving adhesion strength to a Ti layer, (2) enabling the formation of a uniform thin film of TiC on the surface, (3) being customizable to optimize the thickness of the TiC layer by changing the reactive carbon moiety and the size of constituent molecules, (4) being customizable for different polymer dielectrics with use of different end groups as described herein, (5) being fungible with existing and prospective organic adhesion promotion chemistry/toolsets at the Cu-dielectric interface, that eliminate the need for any specialized toolsets, and (6) enabling reliable package architectures in the emerging fields of panel level fan-out architectures, hyper-density packaging and bump pitch scaling in multi-die interconnect bridge (EMIB) architectures.

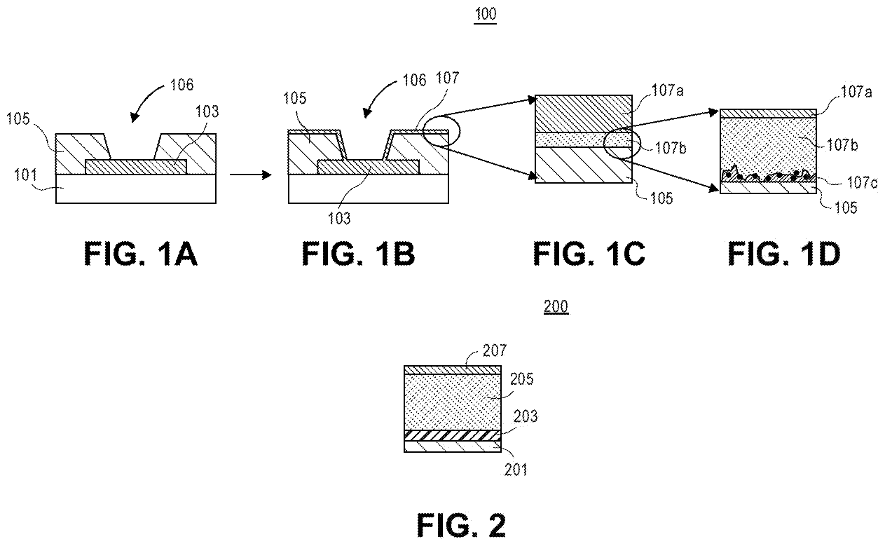

FIGS. 1A-1D illustrate cross-sections of an interconnect structure during a process for forming interconnects according to a previous approach. It should be appreciated that the process used in the previous approach results in the uncontrollable formation of a non-uniform TiC/TiO₂ interfacial layer with low adhesion strength as described herein below.

Referring to FIG. 1A, after one or more operations, an interconnect structure 100 is formed that includes dielectric 101, wiring layer 103, dielectric 105 and via 106. In particular, FIG. 1A shows the interconnect structure 100, after the formation of the via 106, and after the dielectric 105 has been formed on the dielectric 101. In an embodiment, the dielectric 101 is a build-up dielectric. In an embodiment, the dielectric 105 is a PID/SR dielectric (high resolution).

Referring to FIG. 1B, after one or more operations that result in the cross-section shown in FIG. 1A, a Ti/Cu layer 107 is formed on a top surface and via sidewalls of dielectric 105. In an embodiment, the Ti/Cu layer 107 is formed by sputter deposition of the Ti and Cu layers. In other embodiments, the Ti/Cu layer 107 can be formed by other suitable methods of forming the Ti/Cu layer 107.

Referring to FIG. 1C, details of the Ti/Cu layer 107 of structure 100 are shown after one or more operations that result in the cross-section shown in FIG. 1B. In particular, FIG. 1C shows that Ti/Cu layer 107 includes Cu layer 107a and Ti layer 107b. As shown in FIG. 1C, the Cu layer 107a is formed above the Ti layer 107b and the Ti layer 107b is formed above the dielectric layer 105.

Referring to FIG. 1D, details of the Ti-PID interface are shown after one or more operations that result in the cross-section shown in FIG. 1B. In particular, FIG. 1D illustrates the uncontrollable formation of a TiC/TiO₂ interfacial layer 107c at the interface between dielectric 105 (PID) and Ti layer 107b.

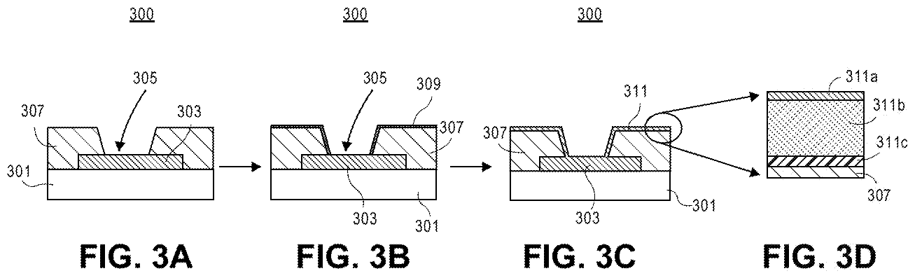

FIG. 2 illustrates an interconnect structure 200 that includes a uniform TiC layer according to an embodiment. In an embodiment, the uniform TiC layer is formed through the controllable generation of TiC through the interaction of carbon atoms of a controlled organic layer such as a self-assembled monolayer (SAM) with impinging Ti atoms. FIG. 2 shows dielectric layer 201, TiC layer 203, Ti layer 205 and Cu layer 207. In an embodiment, the dielectric layer 201 is a PID layer. Referring to FIG. 2, in an embodiment, the dielectric layer 201 is formed on a dielectric material (as shown in FIGS. 3A-3D below), the TiC layer 203 is formed above the dielectric layer 201, the Ti layer 205 is above the TiC layer 203, and the Cu layer 207 is formed on the Ti layer 205.

As a part of the fabrication of the interconnect structure 200, a controlled organic layer such as a SAM is formed on the dielectric layer 201 that enables a controllable formation of the interfacial TiC layer 203. The controlled organic layer is described in detail with reference to FIGS. 3A-3D herein. The TiC layer 203 provides high adhesion strength and improves package reliability. In an embodiment, the interaction of impinging Ti atoms with carbon atoms of the controlled organic layer causes a reactive carbon rich material to be controllably formed on the dielectric surface. Thus, the controlled organic layer acts as a controllable source of active carbon atoms to the impinging Ti atoms in the PVD process. The operation of the controlled organic layer as a controllable generator of active carbon atoms enables a controlled and uniform, formation of a TiC layer and improves interfacial adhesion between the dielectric and Ti.

In an embodiment, the thickness of the TiC layer can be controlled by the use of multi-layers. For example, multi-layers can be formed by the controlled stacking of organic layers such as SAMS (self-assembled monolayers). And, the stacking of organic layers can be used to control the thickness of the TiC layer. For example, each additional organic layer that is formed can cause a controlled increase in the thickness of the TiC layer that results from impinging Ti atoms. Such multi-layers can be a few nanometers to hundreds of nanometers of film thicknesses.

FIGS. 3A-3D illustrate cross-sections of an interconnect structure during a process for forming interconnects that have a uniform TiC layer according to an embodiment. In an embodiment, the TiC layer that is formed provides high adhesion strength between Ti and a dielectric surface upon which the Ti is formed. In an embodiment, the high adhesion strength can improve package reliability.

Referring to FIG. 3A, after one or more operations, the interconnect structure 300 includes dielectric 301, wiring layer 303, via 305 and dielectric layer 307. In an embodiment, the dielectric 301 can be a buildup dielectric. In an embodiment, the dielectric layer 307 can be a high resolution photo-imageable dielectric layer (PID/SR). FIG. 3A shows the dielectric layer 307 on portions of the dielectric 301 and the wiring layer 303 after the formation of the via 305.

Referring to FIG. 3B, after one or more operations that result in the cross-section shown in FIG. 3A, a controlled organic layer 309 is formed on the top surface and via sidewalls of dielectric layer 307. In an embodiment, the controlled organic layer 309 can be formed by spray/dip deposition of an interfacial controlled organic layer. In other embodiments, the controlled organic layer 309 can be formed by other suitable manners of forming a controlled organic layer.

In an embodiment, the formation of the controlled organic layer can include the controlled stacking of organic layers such as SAMS (self-assembled monolayers) as described herein. In an embodiment, the stacking of organic layers can be used to control the thickness of the TiC layer (as described with reference to FIG. 3D).

Referring to FIG. 3C, after one or more operations that result in the cross-section shown in FIG. 3B, a Ti layer/Cu layer 311 is formed above the controlled organic layer 309 that is formed on the top surface and via sidewalls of the dielectric layer 307. In an embodiment, the Ti/Cu layer 311 can be formed by sputter deposition of the Ti and Cu layers. In other embodiments, the Ti/Cu layer 311 can be formed by other suitable manners of forming the Ti/Cu layer 311. In an embodiment, the controlled organic layer 309 can be wholly or partially consumed/eliminated by the interaction between Ti atoms and the controlled organic layer 309 that is described with reference to FIG. 3D. The Ti layer/Cu layer 311 includes Cu layer 311a and Ti layer 311b as is shown in FIG. 3D.

Referring to FIG. 3D, after one or more operations that result in the cross-section shown in FIG. 3C, an interfacial TiC layer 311c is formed. In an embodiment, the TiC layer 311c can be generated between the dielectric layer 307 and the Ti layer 311b.

In an embodiment, the TiC layer 311c is generated by the interaction of impinging Ti atoms with carbon atoms of the controlled organic layer 309 which causes a reactive carbon rich material to be controllably formed on the dielectric surface. Thus, the controlled organic layer 309 acts as a controllable source of active carbon atoms to the impinging Ti atoms. More specifically, the controlled organic layer 309 enables a controlled and uniform, formation of the TiC layer 311c and improves interfacial adhesion between the dielectric and Ti. In an embodiment, when a stacking of organic layers is used to control the thickness of the TiC layer as discussed herein, each additional organic layer that is formed in the stack can cause a controlled increase in the thickness of the TiC layer that results from impinging Ti atoms. In an embodiment, such multi-layers can be a few nanometers to hundreds of nanometers of film thicknesses.

In an embodiment, the molecular design of the controlled organic layer 309 includes non-interacting functional end groups. These end groups include a first functional end group (R1) that chemically bonds to the surface of the dielectric layer 307 material and a second functional end group (R2) that provides a reactive carbon moiety for easily forming the TiC layer 311c. In an embodiment, after the formation of vias, the controlled organic layer 309 is applied in a manner such that the end groups (R1 and R2) do not react with one another. In particular, in an embodiment, R1 attaches to the dielectric layer 307 surface to deliver an ordered array of self-assembled molecules that present R2 moieties (carbon atoms) for reaction with the Ti material that is used to form the Ti layer 311b during the deposition of the Ti material. Thus, the controlled organic layer 309 operates as a controllable generator of active carbon atoms and enables the controlled, uniform, formation of the TiC layer 311c that improves interfacial adhesion between the dielectric layer 307 and the Ti layer 311b. In particular, embodiments enable the enhanced sputter/PVD adhesion of materials such as Ti to dielectrics (e.g., organic dielectrics).

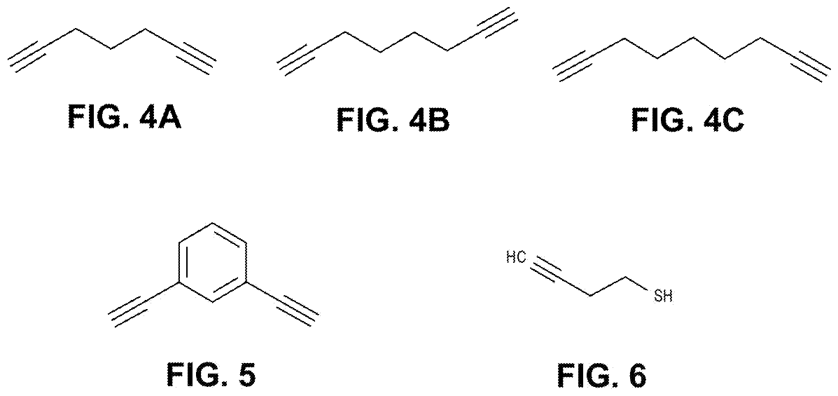

FIG. 4A-4C and FIG. 5 illustrate examples of the basic structure of molecules that can be used to form a controlled organic layer such as a SAM layer. In particular, FIGS. 4A-4C and FIG. 5 show two classes of dialkyne molecules that can be used to form a controlled organic layer. FIGS. 4A-4C show skeletal formulas for respective short chain aliphatic di-alkynes (diyne). FIG. 5 shows the skeletal formula for a short chain aromatic di-alkyne (diyne).

Referring to FIGS. 4A-5, the symmetric bifunctional molecules shown therein are preferred for creating a controlled organic layer, and for improving control over TiC layer formation. In an embodiment, shorter chain bifunctional molecules are preferred for improving control and functional longer chain molecules (e.g. aromatic dialkynes) can be utilized when a thicker TiC layer is desired.

FIG. 6 is an example of an asymmetrical bifunctional variant that can be used in the formation of a controlled organic layer according to an embodiment. Referring to FIG. 6, the skeletal formula for asymmetrical bifunctional variant But-3-yne-1-thiol is shown. In an embodiment, functional groups like dienes, thiols, etc., can be used along with asymmetrical bifunctional variants as described herein to form a uniform SAM layer. In an embodiment, functional groups containing nitrogen atoms (e.g. amines, azoles, pyroles etc.) can be used. In an embodiment, in using such functional groups, the TiN layer that is formed can be less strong than a TiC layer. In an embodiment, in general, functional groups containing oxygen atoms may not be used for applications described herein because the formation of TiO₂ can be detrimental to the process.

It should be appreciated that the molecules described with reference to FIGS. 4A-4C, FIG. 5 and FIG. 6 are examples only. In an embodiment, organic layers can be formed by other molecules that can provide this function as well.

In an embodiment, reliable package architectures are enabled for emerging fields of panel level fan-out architectures, hyper density packaging and bump pitch scaling in EMIB architectures in electronic packaging applications. Thus, in an embodiment, cutting edge packaging technologies, are facilitated.

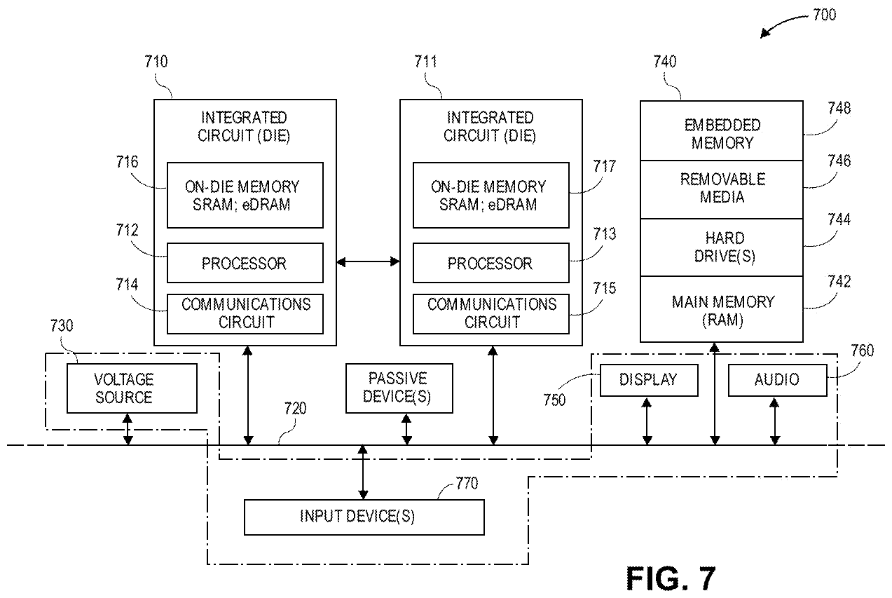

FIG. 7 is a schematic of a computer system 700, in accordance with an embodiment of the present invention. The computer system 700 (also referred to as the electronic system 700) as depicted can embody interconnects that can include Ti layer/Cu interfacial layers for providing adhesion with organic dielectric material, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In an embodiment, the computer system 700 can include a plurality of integrated circuit die 710 that can include one or more interconnection devices that include the interconnect structure 200 that is described with reference to FIG. 2. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, interconnects that can include a Ti layer/Cu interfacial layer for providing adhesion with organic dielectric material, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a package substrate having interconnects that can include a Ti layer/Cu interfacial layer for providing adhesion with organic dielectric material, according to any of the several disclosed embodiments and their equivalents, an electronic system, a computer system, one or more methods of fabricating an integrated circuit, and one or more methods of fabricating an electronic assembly that includes a package substrate having interconnects that can include a Ti layer/Cu interfacial layer for providing adhesion with organic dielectric material, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having interconnects that can include a Ti layer/Cu interfacial layer for providing adhesion with organic dielectric material embodiments and their equivalents. A foundation substrate may be included, as represented by the dashed line of FIG. 7. Passive devices may also be included, as is also depicted in FIG. 7.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

### Example Embodiment 1

An interconnection structure including a dielectric layer, an interfacial TiC layer on the dielectric layer, the interfacial TiC layer having a uniform thickness, and a Ti layer on the TiC layer.

### Example Embodiment 2

The interconnection structure of example embodiment 1, further comprising a via in the dielectric layer, wherein the interfacial TiC layer and the Ti layer are in the via.

### Example Embodiment 3

The interconnection structure of example embodiment 1 or 2, wherein the dielectric layer is a photoimageable dielectric (PID).

### Example Embodiment 4

The interconnection structure of example embodiment 3, further comprising a buildup dielectric layer underneath the PID.

### Example Embodiment 5

The interconnection structure of example embodiment 1 or 4, further comprising a Cu layer on the Ti layer.

### Example Embodiment 6

An interconnection structure including a dielectric layer; an interfacial TiN layer on the dielectric layer having a uniform thickness, and a Ti layer on the TiN layer.

### Example Embodiment 7

The interconnection structure of example embodiment 6, further comprising a via in the dielectric layer, wherein the interfacial TiN layer and the Ti layer are in the via.

### Example Embodiment 8

The interconnection structure of example embodiment 6 or 7, wherein the dielectric layer is a photoimageable dielectric (PID).

### Example Embodiment 9

The interconnection structure of example embodiment 8, further comprising a buildup dielectric layer underneath the PID.

### Example Embodiment 10

The interconnection structure of example embodiment 6 or 9, further comprising a Cu layer on the Ti layer.

### Example Embodiment 11

A system, including a storage component, a plurality of integrated circuit die including one or more interconnection structures, the interconnection structures including a dielectric layer, an interfacial TiC layer on the dielectric layer, the interfacial TiC layer having a uniform thickness, and a Ti layer on the TiC layer.

### Example Embodiment 12

The system of example embodiment 11, further comprising a via in the dielectric layer, wherein portions of the interfacial TiC layer and the Ti layer are in the via.

### Example Embodiment 13

The system of example embodiment 11 or 12, wherein the dielectric layer is a photoimageable dielectric (PID) layer.

### Example Embodiment 14

The system of example embodiment 13, further comprising a buildup dielectric layer underneath the PID layer.

### Example Embodiment 15

The system of example embodiment 11 or 14, further comprising a Cu layer on the Ti layer.

### Example Embodiment 16

A method including forming a dielectric layer, forming a controllable organic layer on the dielectric layer, forming a Ti layer on the controllable organic layer, and forming a TiC layer under the Ti layer.

### Example Embodiment 17

The method of example embodiment 16, wherein forming the TiC layer includes causing Ti atoms to impinge upon the controllable organic layer.

### Example Embodiment 18

The method of example embodiment 16 or 17, wherein forming the TiC layer causes a partial or a complete elimination of the controllable organic layer.

### Example Embodiment 19

The method of example embodiment 16, 17 or 18 wherein forming the controllable organic layer comprises forming a plurality of controllable organic layers.

### Example Embodiment 20

The method of example embodiment 19, wherein a thickness of the TiC layer that is formed corresponds to a number of the plurality of controllable organic layers that are formed.

### Example Embodiment 21

The method of example embodiment 16 or 19, further comprising forming a Cu layer on the Ti layer.

### Example Embodiment 22

The method of example embodiment 16, wherein forming the controllable organic layer includes forming a layer of material that includes symmetrical bifunctional molecules.

### Example Embodiment 23

The method of example embodiment 16, wherein forming the controllable organic layer includes forming a layer of material that includes a short chain dialkyne.

### Example Embodiment 24

The method of example embodiment 23, wherein forming the short chain dialkyne includes forming an aromatic dialkyne.

### Example Embodiment 25

The method of example embodiment 23, wherein forming the short chain dialkyne includes forming an aliphatic dialkyne layer.

What is claimed is:

1. An interconnection structure, comprising:
a dielectric layer;
an interfacial TiC layer on the dielectric layer, the interfacial TiC layer having a uniform thickness; and
a Ti layer on the TiC layer.

2. The interconnection structure of claim 1, further comprising a via in the dielectric layer, wherein the interfacial TiC layer and the Ti layer are in the via.

3. The interconnection structure of claim 1, wherein the dielectric layer is a photoimageable dielectric (PID).

4. The interconnection structure of claim 3, further comprising a buildup dielectric layer underneath the PID.

5. The interconnection structure of claim 1, further comprising a Cu layer on the Ti layer.

6. An interconnection structure, comprising:
a dielectric layer;
an interfacial TiN layer on the dielectric layer, the interfacial TiN layer having a uniform thickness; and
a Ti layer on the TiN layer.

7. The interconnection structure of claim 6, further comprising a via in the dielectric layer, wherein the interfacial TiC layer and the Ti layer are in the via.

8. The interconnection structure of claim 6, wherein the dielectric layer is a photoimageable dielectric (PID).

9. The interconnection structure of claim 8, further comprising a buildup dielectric layer underneath the PID.

10. The interconnection structure of claim 6, further comprising a Cu layer on the Ti layer.

11. A system, comprising:
one or more storage components; and
one or more integrated circuit die including one or more interconnection structures, the interconnection structures including:
a dielectric layer;
an interfacial TiC layer on the dielectric layer, the TiC layer having a uniform thickness; and
a Ti layer on the TiC layer.

12. The system of claim 11, further comprising a via in the dielectric layer, wherein portions of the interfacial TiC layer and the Ti layer are in the via.

13. The system of claim 11, wherein the dielectric layer is a photoimageable dielectric (PID) layer.

14. The system of claim 13, further comprising a buildup dielectric layer underneath the PID layer.

15. The system of claim 11, further comprising a Cu layer on the Ti layer.

16. A method, comprising:
forming a dielectric layer;
forming a controllable organic layer on the dielectric layer;
forming a Ti layer on the controllable organic layer; and
forming a TiC layer under the Ti layer.

17. The method of claim 16, wherein forming the TiC layer includes causing Ti atoms to impinge upon the controllable organic layer.

18. The method of claim 16, wherein forming the TiC layer includes a partial or complete elimination of the controllable organic layer.

19. The method of claim 16, wherein forming the controllable organic layer comprises forming a plurality of controllable organic layers.

20. The method of claim 19, wherein a thickness of the TiC layer that is formed corresponds to a number of the plurality of controllable organic layers that are formed.

21. The method of claim 13, further comprising forming a Cu layer on the Ti layer.

22. The method of claim 13, wherein forming the controllable organic layer includes forming a layer of material that includes symmetrical bifunctional molecules.

23. The method of claim 13, wherein forming the controllable organic layer includes forming a layer of material that includes a short chain dialkyne.

24. The method of claim 16, wherein forming the short chain dialkyne includes forming an aromatic dialkyne.

25. The method of claim 16, wherein forming the short chain dialkyne includes forming an aliphatic dialkyne layer.
